(19) United States
(12) Patent Application Publication
(10) Pub. No.: US 2025/0160146 A1
(43) Pub. Date: May 15, 2025

(54) DISPLAY DEVICE AND METHOD OF MANUFACTURING THE SAME

(71) Applicant: SAMSUNG DISPLAY CO., LTD., YONGIN-SI (KR)

(72) Inventors: Kang Moon JO, Yongin-si (KR); Seung Hyun PARK, Yongin-si (KR); Sun Kwang KIM, Yongin-si (KR); Dong Yoon LEE, Yongin-si (KR); Seong Young LEE, Yongin-si (KR)

(21) Appl. No.: 18/770,773

(22) Filed: Jul. 12, 2024

(30) Foreign Application Priority Data
Nov. 14, 2023 (KR) 10-2023-0157652

(51) Int. Cl. H10K 59/131; H01L 27/12; H10K 59/12; H10K 59/121

(52) U.S. Cl. CPC H10K 59/131; H10K 59/1201; H10K 59/1213; H10D 86/441; H10D 86/60

(57) ABSTRACT

A display device includes a substrate, driving transistors, an insulating layer, and light emitting elements. The driving transistors are disposed in pixel areas on the substrate and each includes a first electrode and a second electrode. The insulating layer is disposed over the driving transistors to cover the first electrodes and the second electrodes of the driving transistors and has contact holes respectively overlapping with the first electrodes of the driving transistors. The light emitting elements are disposed on the insulating layer and include pixel electrodes respectively overlapping with the first electrodes of the driving transistors. In addition, an insulating pattern is disposed in at least one of the contact holes to prevent a corresponding pixel area from emitting light.

### CROSS-REFERENCE TO RELATED APPLICATION

The present application claims priority under 35 U.S.C. § 119 (a) to Korean patent application number 10-2023-0157652, filed on Nov. 14, 2023, in the Korean Intellectual Property Office, the disclosure of which is incorporated by reference herein in its entirety.

### 1. TECHNICAL FIELD

The present disclosure generally relates to a display device and a method of manufacturing the same.

### 2. DISCUSSION OF RELATED ART

A variety of display devices have been developed. Examples include Organic Light Emitting Displays (OLEDs) and Liquid Crystal Displays (LCDs). These display devices may include a display panel having a plurality of light emitting elements such as Light Emitting Diodes (LEDs). Examples of LEDs include organic LEDs which use organic material such as a fluorescent material, and inorganic LEDs which use inorganic materials such as a fluorescent material.

However, in a process of manufacturing lines and switching and driving thin film transistors for a display device, lighting defects may occur in the light emitting elements due to characteristic deterioration of the driving thin film transistors or occurrence of internal short circuits. Accordingly, pixel areas in which lighting defects occur should be repaired.

### SUMMARY

Embodiments provide a display device and a method of manufacturing the same, which can have increased efficiency by repairing lighting defects of pixels.

In accordance with an aspect of the present disclosure, there is provided a display device including: a substrate; driving transistors disposed in pixel areas on the substrate, the driving transistors each including a first electrode and a second electrode; an insulating layer disposed over the driving transistors to cover the first electrodes and the second electrodes of the driving transistors, the insulating layer having contact holes respectively overlapping with the first electrodes of the driving transistors; light emitting elements disposed on the insulating layer, the light emitting elements including pixel electrodes respectively overlapping with the first electrodes of the driving transistors; and an insulating pattern disposed in at least one of the contact holes to prevent a corresponding one of the pixel areas from emitting light.

The pixel electrodes may include a first pixel electrode and a second pixel electrode. The first pixel electrode may overlap with the insulating pattern. The first pixel electrode may be electrically separated from a first electrode overlapping with the first pixel electrode among the first electrodes of the driving transistors by the insulating pattern.

The second pixel electrode may be electrically connected to a first electrode overlapping with the second pixel electrode among the first electrodes of the driving transistors through another of the contact holes.

The insulating pattern may include an inorganic material or an organic material.

Pixel circuits may be respectively disposed in the pixel areas on the substrate. The pixel circuits may include the driving transistors. A pixel circuit of a pixel area overlapping with the insulating pattern among the pixel areas may correspond to a defective pixel circuit.

The display device may further include a repair line extending to overlap with a common voltage line from a first pixel electrode overlapping with the insulating pattern among the pixel electrodes.

The common voltage line may be disposed on the bottom of the insulating layer. The repair line may be electrically connected to the common voltage line through another contact hole formed in the insulating layer.

The repair line may be formed in the same layer as the first pixel electrode.

The repair line may include a conductive material.

The first pixel electrode may be electrically connected to the common voltage line by the repair line.

The pixel areas may extend in a first direction. The common voltage line may extend in the first direction to overlap with the pixel areas.

In accordance with another aspect of the present disclosure, there is provided a method of manufacturing a display device, the method including: forming driving transistors each including a first electrode and a second electrode in pixel areas on a substrate; forming an insulating layer covering the first electrodes and the second electrodes of the driving transistors, the insulating layer having contact holes respectively overlapping with the first electrodes of the driving transistors; and forming, on the insulating layer, light emitting elements including pixel electrodes respectively overlapping with the first electrodes of the driving transistors, wherein the forming of the insulating layer further includes forming an insulating pattern in at least one of the contact holes to prevent a corresponding one of the pixel areas from emitting light . . . .

The pixel electrodes may include a first pixel electrode and a second pixel electrode. The first pixel electrode may overlap with the insulating pattern. The first pixel electrode may be electrically separated from a first electrode overlapping with the first pixel electrode among the first electrodes of the driving transistors by the insulating pattern.

The second pixel electrode may be electrically connected to a first electrode overlapping with the second pixel electrode among the first electrodes of the driving transistors through another of the contact holes.

The insulating pattern may include an inorganic material or an organic material.

The method may further include forming a repair line extending to overlap with a common voltage line from a first pixel electrode overlapping with the insulating pattern among the pixel electrodes.

The first pixel electrode may be electrically connected to the common voltage line by the repair line. The repair line may include a conductive material.

In accordance with one embodiment, a pixel includes a light emitting element; a pixel circuit configured to drive the light emitting element; and an insulating pattern to electrically disconnect the pixel circuit from the light emitting element when the pixel is defective. The pixel may further include a planarization insulating layer between a driving transistor of the pixel circuit and the light emitting element, wherein the planarization insulating layer includes a contact hole which includes the insulating pattern. The pixel may further include a repair line electrically connecting an electrode of the light emitting element to a supply voltage, the supply voltage configured to stabilize the electrode of the light emitting element when the pixel is defective. The insulating pattern may include an insulating ink.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a block diagram illustrating a display device in accordance with an embodiment of the present disclosure.

FIG. 2 is a block diagram illustrating an embodiment of pixel areas included in unit pixels shown in FIG. 1.

FIG. 3 is a circuit diagram illustrating an embodiment of any one of the pixel circuits shown in FIG. 2.

FIG. 4 is a plan view illustrating an embodiment of a first conductive layer included in first to third pixels shown in FIG. 2.

FIG. 5 is a plan view illustrating an embodiment of an active layer disposed on the first conductive layer shown in FIG. 4.

FIG. 6 is a plan view illustrating an embodiment of a second conductive layer disposed on the active layer shown in FIG. 5.

FIG. 7 is a plan view illustrating an embodiment of a third conductive layer disposed on the second conductive layer shown in FIG. 6.

FIG. 8 is a plan view illustrating an embodiment of a pixel electrode layer disposed on the third conductive layer shown in FIG. 7.

FIG. 9 is a plan view illustrating an insulating pattern provided in a unit pixel shown in FIG. 8.

FIG. 10 is a plan view illustrating a repair line provided in the unit pixel shown in FIG. 9.

FIG. 11 is a sectional view illustrating portions of a pixel circuit and a light emitting element, taken along section line I-I′ shown in FIG. 9, including an insulating pattern in a contact hole of a defective pixel.

FIG. 12 is a flowchart illustrating an embodiment of a method of manufacturing the display device.

### DETAILED DESCRIPTION

Hereinafter, embodiments of the present disclosure will be described in more detail with reference to the accompanying drawings. In the description below, only a necessary part to understand an operation according to the present disclosure is described and the descriptions of other parts are omitted in order not to unnecessarily obscure subject matters of the present disclosure. In addition, the present disclosure is not limited to exemplary embodiments described herein, but may be embodied in various different forms. Rather, exemplary embodiments described herein are provided to thoroughly and completely describe the disclosed contents and to sufficiently transfer the ideas of the disclosure to a person of ordinary skill in the art.

In the entire specification, when an element is referred to as being “connected” or “coupled” to another element, it can be directly connected or coupled to the another element or be indirectly connected or coupled to the another element with one or more intervening elements interposed therebetween.

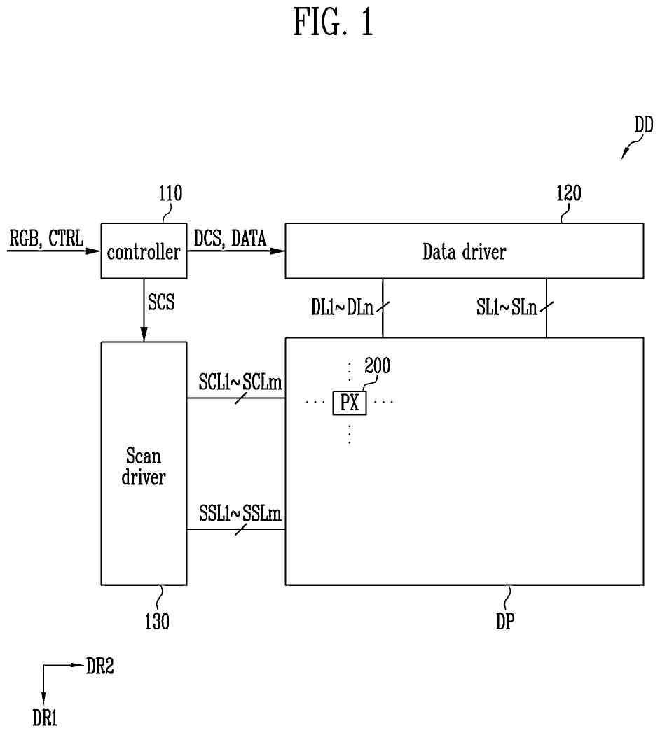

FIG. 1 is a block diagram illustrating a display device DD in accordance with an embodiment of the present disclosure.

Referring to FIG. 1, the display device DD may include a display panel DP, a controller 110, a data driver 120, and a scan driver 130.

The display panel DP may also include a plurality of unit pixels PX. The plurality of unit pixels PX may be arranged in a first direction DR1 and a second direction DR2. Also, the display panel DP may be connected to a plurality of scan lines SCL1 to SCLm and a plurality of data lines DL1 to DLn. The plurality of scan lines SCL1 to SCLm and the plurality of data lines DL1 to DLn may be disposed on the display panel DP and intersect each other at respective ones of the unit pixels PX. The plurality of unit pixels PX in the display panel DP may be electrically connected to the scan lines SCL1 to SCLm and the data lines DL1 to DLn.

Also, the plurality of unit pixels PX may be electrically connected to sensing lines SL1 to SLn and sensing control lines SSL1 to SSLm. The sensing control lines SSL1 to SSLm and the sensing lines SL1 to SLn may be arranged on the display panel DP while intersecting each other. As described in greater detail below, the sensing lines may apply an initialization voltage Vint to corresponding unit pixels.

The display panel DP may be various types of panels. One non-limiting example is an Organic Light Emitting Diode (OLED) panel. The kind and number of lines disposed in the display panel DP may vary according to a structure of the unit pixels, the type of display panel being implemented, and/or various other features of the display panel.

The controller 110 may control operations of the data driver 120 and the scan driver 130. In operation, the controller 110 may receive an image signal RGB and a control signal CTRL. The controller 110 may provide a first control signal SCS to the scan driver 130 to control the scan driver 130 to apply a scan signal to the scan lines SCL1 to SCLm at a timing implemented in each of a plurality of frames. Additionally, the controller 110 may be configured to generate an image data signal DATA, which may be obtained by converting a data format of the image signal RGB to a form suitable for interface specifications of the data driver 120. The controller 110 may output a second control signal DCS to the data driver 120 to control the data driver 120 to apply data voltages to the data lines DL1 to DLn when the scan signal is supplied to the scan lines SCL1 to SCLm.

The controller 110 may be a timing controller or a control device capable of performing another control function, including the timing controller. The controller 110 may be implemented as a component separate from the data driver 120, or be implemented as an integrated circuit together with the data driver 120.

The data driver 120 may output data signals to the plurality of data lines DL1 to DLn. For example, the data driver 120 may receive the second control signal DCS and the image data signal DATA from the controller 110. The data driver 120 may convert the image data signal DATA into data signals, and output the data signals to respective ones of the data lines DL1 to DLn. The data signals may be analog voltages corresponding to grayscale values of the image data signal DATA. For example, when a specific scan line is selected by the scan driver 130, the data driver 120 may supply data voltages in an analog form to the plurality of data lines DL1 to DLn.

The data driver 120 may supply an initialization voltage Vint to the sensing lines SL1 to SLn during a display period. After that, in accordance with an embodiment, when a sensing control signal is supplied to any one of the sensing control lines SSL1 to SSLm by the scan driver 130, the data driver 120 may sense emission characteristics of corresponding pixels PX through the sensing lines SL1 to SLn.

In an embodiment, it is illustrated that the sensing lines SL1 to SLn are connected to the data driver 120. However, in some embodiments, a sensing driver separate from the data driver 120 may be provided in the display device DD, e.g., the data driver 120 and the sensing driver may be implemented as components that are separate from each other.

The scan driver 130 may operate in response to the first control signal SCS from the controller 110. The scan driver 130 may output a scan signal to the plurality of scan lines SCL1 to SCLm. In one embodiment, the scan driver 130 may include a gate driver. The scan driver 130 may sequentially supply scan signals to the scan lines SCL1 to SCLm according to the first control signal SCS from the controller 110.

The unit pixels PX that receive the scan signal may receive analog voltages of grayscale values corresponding to the image data signal DATA. Therefore, the unit pixels PX may output light with a luminance corresponding to the analog voltages. Accordingly, an image may be displayed on the display panel DP.

At least one of the controller 110, the data driver 120, or the scan driver 130 may be mounted in the form of integrated circuit chips on the display panel DP. Other ones of the controller 110, the data driver 120, or the scan driver 130 may be attached, for example, in the form of a Tape Carrier Package (TCP) to the display panel DP, or be mounted on a separated printed circuit board.

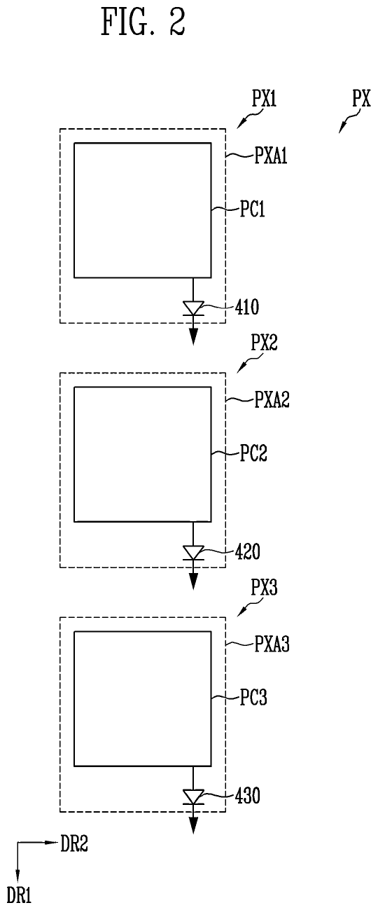

FIG. 2 is a block diagram illustrating an embodiment of pixel areas included in the unit pixels shown in FIG. 1.

Referring to FIG. 2, each of the unit pixels PX may include a plurality of pixels (or sub-pixels), e.g., each unit pixel PX may include a first pixel PX1, a second pixel PX2, and a third pixel PX3. These pixels may emit light of predetermined colors. For example, the first pixel PX1 may emit red light R, the second pixel PX2 may emit green light G, and the third pixel PX3 may emit blue light B. Alternatively, each of the unit pixels PX may emit a different combination of light colors, and/or may further include a fourth pixel PX4 that emits white light W.

In FIG. 2, for convenience of description, the first to third pixels PX1 to PX3 are shown to be sequentially disposed. However, embodiments are not limited thereto. For example, the present disclosure may be applied to a different number (e.g., two) pixels which are sequentially disposed.

Each of the pixels PX1 to PX3 may include a pixel circuit and at least one light emitting element. For example, the first pixel PX1 may include a first pixel circuit PC1 and a first light emitting element 410, which is controlled by the first pixel circuit PC1 to emit light. The second pixel PX2 may include a second pixel circuit PC2 and a second light emitting element 420, which is controlled by the second pixel circuit PC2 to emit light. The third pixel PX3 may include a third pixel circuit PC3 and a third light emitting element 430, which is controlled by the third pixel circuit PC3 to emit light. Each of the light emitting elements 410 to 430 may be, for example, an organic light emitting diode.

First to third pixel areas PXA1 to PXA3 may be arranged in a predetermined pattern, e.g., may be sequentially arranged in the first direction DR1 on a substrate. The first pixel circuit PC1 of the first pixel PX1 may be disposed in the first pixel area PXA1 among the first to third pixel areas PXA1 to PXA3 arranged in the first direction DR1. The second pixel circuit PC2 of the second pixel PX2 may be disposed in the second pixel area PXA2 among the first to third pixel areas PXA1 to PXA3 arranged in the first direction DR1. The third pixel circuit PC3 of the third pixel PX3 may be disposed in the third pixel area PXA3 among the first to third pixel areas PXA1 to PXA3 arranged in the first direction DR1. However, the arrangement of the pixel areas PXA1, PXA2, and PXA3 shown in FIG. 2 is merely illustrative, and embodiments are not limited thereto. The pixel areas PXA1, PXA2, and PXA3 may be disposed in a different arrangement or pattern in other embodiments.

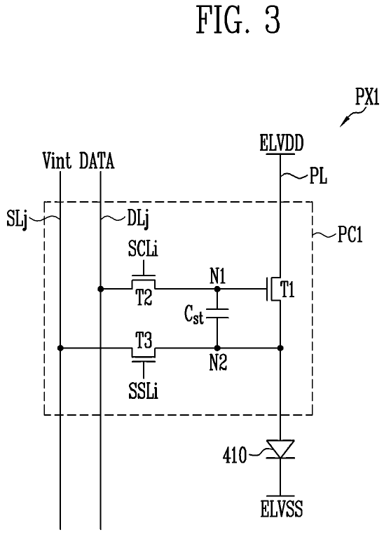

FIG. 3 is a circuit diagram illustrating an embodiment of a pixel circuit which is representative of any one of the pixel circuits shown in FIG. 2. The first pixel PX1 is provided as a representative example. Hereinafter, the first pixel PX1 shown in FIG. 2 will be described with reference to FIG. 3, but the second pixel PX2 and the third pixel PX3, which are shown in FIG. 2, may be configured similarly to the first pixel PX1.

Referring to FIG. 3, the first pixel PX1 may include the first pixel circuit PC1 and a first light emitting element 410 connected to the first pixel circuit PC1. The first pixel circuit PC1 may include a plurality of transistors and at least one capacitor. For example, the first pixel circuit PC1 may include a first transistor T1, a second transistor T2, a third transistor T3, and a storage capacitor Cst. The first transistor T1 may be a driving transistor, the second transistor T2 may be a switching transistor, and the third transistor T3 may be a sensing transistor. Each of the first transistor T1, the second transistor T2, and the third transistor T3, which are shown in FIG. 3, is illustrated as an N-type transistor which, for example, is a thin film transistor, but the present disclosure is not limited thereto. For example, at least one of the first to third transistors T1 to T3 may be a P-type transistor.

A first electrode of the first transistor T1 may be connected (or coupled) to a driving voltage line PL, and a second electrode of the first transistor T1 may be connected to a first pixel electrode (or anode electrode) of the first light emitting element 410. A gate electrode of the first transistor T1 may be connected to a first node N1. For example, the first electrode may be a source electrode, and the second electrode may be a drain electrode. The first transistor T1 may control an amount of driving current supplied to the first light emitting element 410, corresponding to a voltage of the first node N1 that corresponds to the received data, e.g., corresponding to an image data signal DATA.

A first electrode of the second transistor T2 may be connected to a jth data line DLj, and a second electrode of the second transistor T2 may be connected to the first node N1. In addition, a gate electrode of the second transistor T2 may be connected to an ith scan line SCLi. The second transistor T2 may be turned on when a signal having a turn-on voltage (e.g., a voltage having a high level) is supplied from the ith scan line SCLi. When turned on, the second transistor T2 may electrically connect the jth data line DLj and the first node N1 to each other. An image data signal DATA of a corresponding frame may be supplied to the jth data line DLj. The data signal may be transferred to the first node N1. The data signal transferred to the first node N1 may be charged (or stored) in the storage capacitor Cst.

A first electrode of the storage capacitor Cst may be connected to the first node N1, and a second electrode of the storage capacitor Cst may be connected to a second node N2. The storage capacitor Cst may charge (or store) a voltage corresponding to the data signal supplied to the first node N1, and may maintain the charged voltage for a predetermined time, e.g., until a data signal of a next frame is supplied.

A first electrode of the third transistor T3 may be connected to a jth sensing line SLj, and a second electrode of the third transistor T3 may be connected to the second node N2. The second node N2 may be connected to the first light emitting element 410. A gate electrode of the third transistor T3 may be connected to an ith sensing control line SSLi. The third transistor T3 may be turned on when a signal having a turn-on voltage (e.g., a voltage having a high level) is supplied to the ith sensing control line SSLi during a sensing period. When turned on, the third transistor T3 may electrically connect the jth sensing line SLj and the second node N2 to each other. The third transistor T3 may provide an initialization voltage Vint to the second node N2 through the ith sensing control line SSLi.

In some embodiments, the sensing period may be a period in which characteristic information (e.g., a threshold voltage of the first transistor T1, and the like) of the unit pixels PX (or the respective first to third pixels PX1 to PX3) are extracted. During the sensing period, the first transistor T1 may be turned on. The first transistor T1 may be connected to the sensing line SL through the third transistor T3. Characteristic information of the first pixel PX1 (e.g., including the threshold voltage of the first transistor T1, and the like) may be extracted through the sensing line SL.

The first light emitting element 410 may include the first pixel electrode (or anode electrode) and a second pixel electrode (or cathode electrode). A common voltage ELVSS may be applied to the second pixel electrode of the first light emitting element 410. The common voltage ELVSS may be a ground voltage or a predetermined reference voltage that is a voltage higher or lower than the ground voltage. The common voltage ELVSS may vary according to a driving state such as image driving or sensing driving.

The first pixel circuit PC1 may be a pixel circuit of a pixel arranged on an ith row and a jth column (i is a positive integer smaller than or equal to m and j is a positive integer smaller than or equal to n). Also, the first pixel circuit PC1 may be connected to the jth sensing line SLj and the ith sensing control line SSLi. The first pixel circuit PC1 may control the first light emitting element 410 to emit light in response to signals received through the ith scan line SCLi and the jth data line DLj.

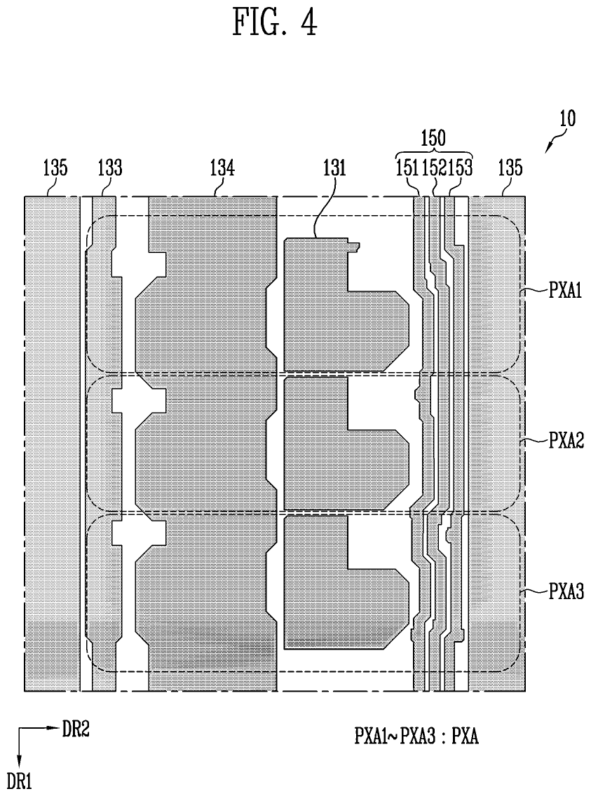

FIG. 4 is a plan view illustrating an embodiment of a first conductive layer included in the first to third pixels shown in FIG. 2. The plan view may be an overlay view which is representative of the first conductive layer of the first to third pixels.

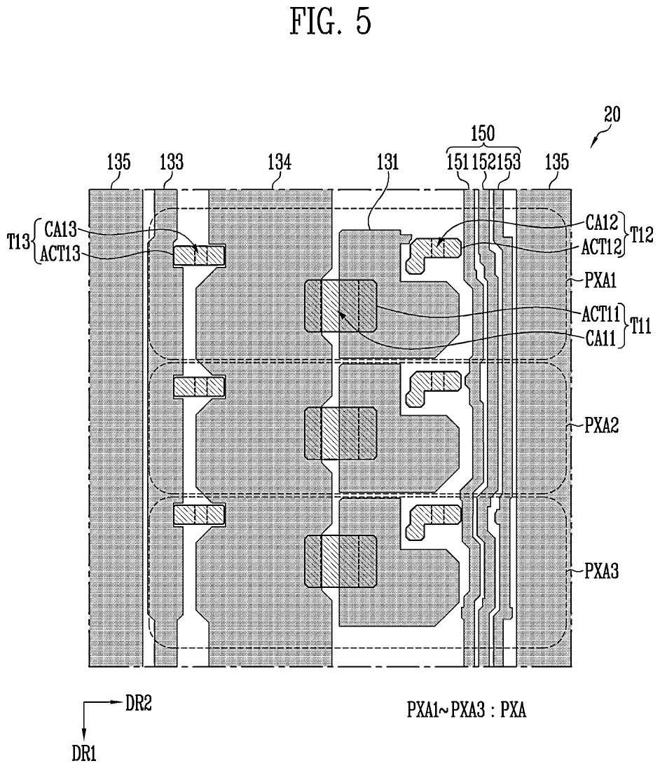

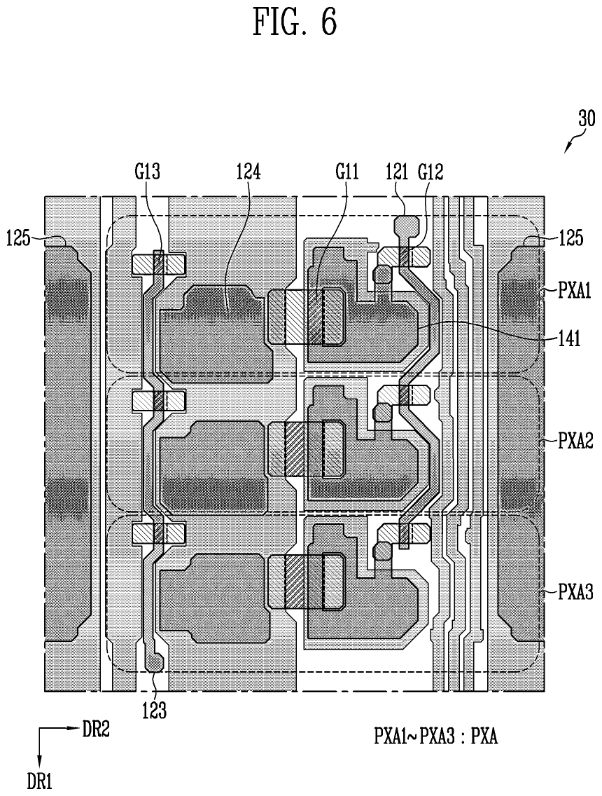

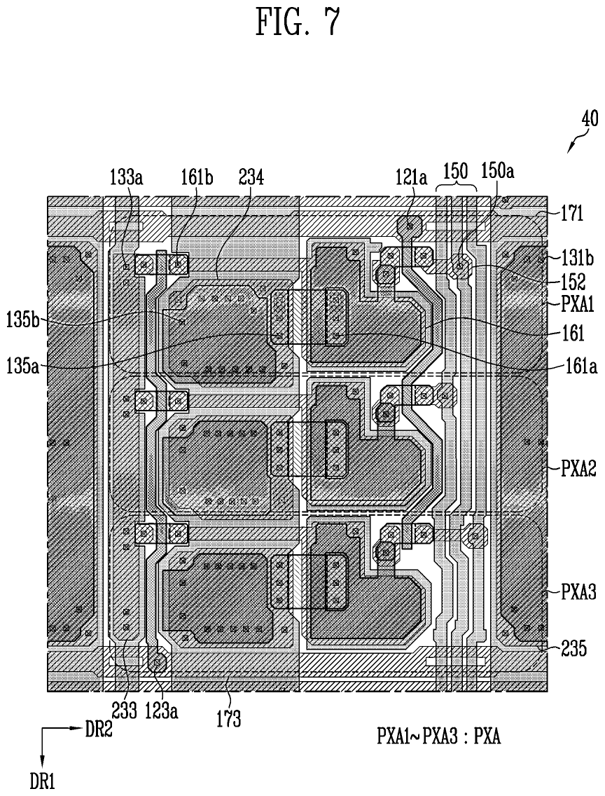

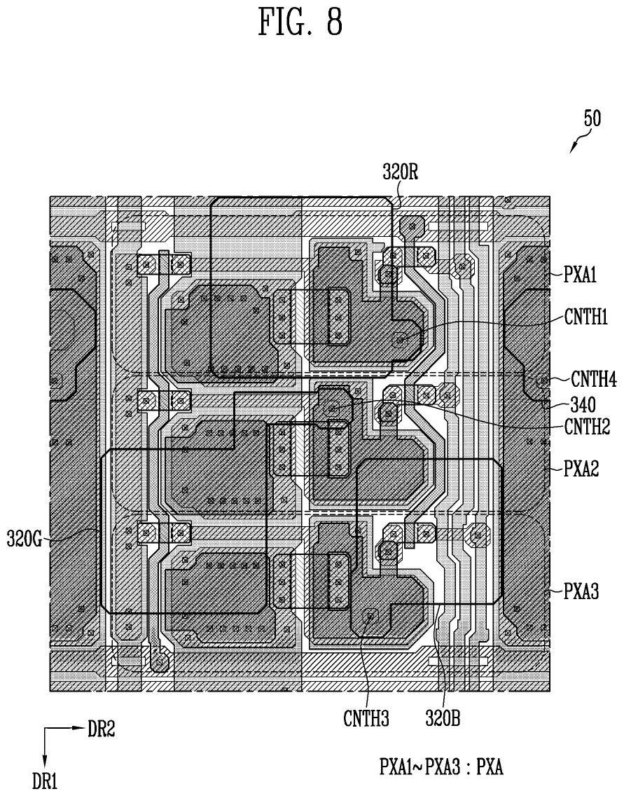

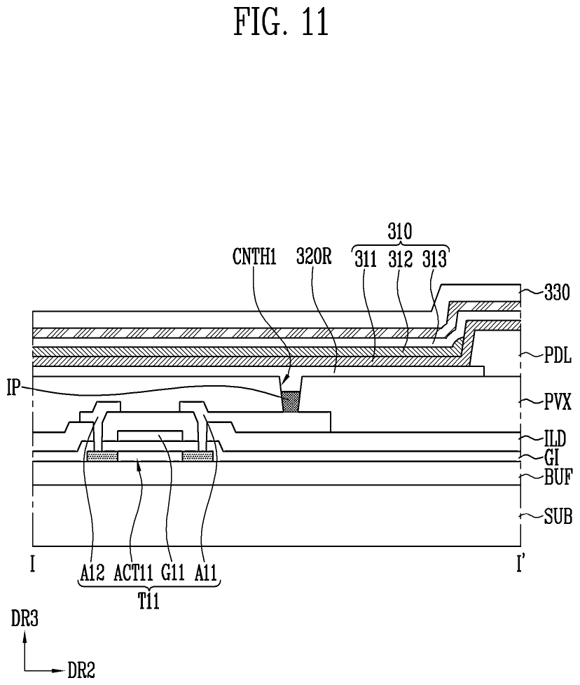

The display panel DP may include, on a substrate (e.g., see FIG. 11), a first conductive layer 10, an active layer 20 (see FIG. 5), a second conductive layer 30 (see FIG. 6), a third conductive layer 40 (see FIG. 7), and a pixel electrode layer 50 (see FIG. 8).

Referring to FIG. 4, first to third pixel areas PXA1 to PXA3 may be sequentially arranged in the first direction DR1. In addition, the first to third pixel circuits PC1 to PC3 and the first to third light emitting elements 410 to 430, which are shown in FIG. 2, may be disposed in the first to third pixel areas PXA1 to PXA3. The pixel circuits may be configured substantially similarly to one another in corresponding pixel areas. Hereinafter, the technical scope of the present disclosure will be described based on the first pixel area PXA1. Each of the second pixel area PXA2 and the third pixel area PXA3 may be configured in a manner similar to the first pixel area PXA1.

The first conductive layer 10 may be formed on the substrate. The first conductive layer 10 may be a light blocking layer that blocks light introduced through a lower surface of the substrate. For example, the first conductive layer 10 may block light introduced to an active layer 20 of the first transistor T1 (see FIG. 3) through the lower surface of the substrate, thereby preventing a malfunction of the first transistor T1. For example, at least a portion of the first conductive layer 10 may be disposed on the substrate to overlap with the gate electrode of the first transistor T1.

The first conductive layer 10 may be electrically connected to transistors. The first conductive layer 10 may include an auxiliary initialization voltage line 133, an auxiliary driving voltage line 134, an auxiliary common voltage line 135, a first auxiliary lower electrode 131, and data lines 150. The auxiliary initialization voltage line 133, the auxiliary driving voltage line 134, the auxiliary common voltage line 135, the first auxiliary lower electrode 131, and the data lines 150 may, for example, be formed through the same or a different process.

The auxiliary initialization voltage line 133, the auxiliary driving voltage line 134, the auxiliary common voltage line 135, and the data lines 150 may generally extend along the first direction DR1. The auxiliary initialization voltage line 133, the auxiliary driving voltage line 134, the auxiliary common voltage line 135, and the data lines 150 may be disposed to be spaced apart from each other (and thus may not be electrically connected to each other) in the second direction DR2.

The data lines 150 may include a first data line 151, a second data line 152, and a third data line 153. The first data line 151, the second data line 152, and the third data line 153 may be disposed to be spaced apart from (and thus not electrically connected to) each other at a predetermined distance. Any one of the data lines 150 may serve as the data line DLj included in the first pixel circuit PC1 shown in FIG. 3.

In addition, the first auxiliary lower electrode 131 may be separately formed of each pixel area. First auxiliary lower electrodes of the first to third pixel areas PXA1 to PXA3 may be disposed to be spaced apart from each other in the first direction DR1.

FIG. 5 is a plan view illustrating an embodiment of an active layer disposed on the first conductive layer shown in FIG. 4. The active layer may include active (channel) regions of transistors used in the pixel circuits, as will be described in greater detail below.

Referring to FIG. 5, a first pixel circuit PC1 of a first pixel PX1 disposed in the first pixel area PXA1 may include a first driving transistor T11, a first switching transistor T12, and a first sensing transistor T13. The first driving transistor T11, the first switching transistor T12, and the first sensing transistor T13 may correspond to the transistors T1 to T3 included in the first pixel circuit PC1 shown in FIG. 3.

An active layer 20 may be disposed on the first conductive layer 10 shown in FIG. 4. The active layer 20 may include active layers of the first driving transistor T11, the first switching transistor T12, and the first sensing transistor T13, and the active layer may all be disposed in the same layer. The active layers may form channels of the aforementioned transistors. The active layer 20 may include a silicon semiconductor material or an oxide semiconductor material. For example, the active layer 20 may include amorphous silicon, polycrystalline silicon, and the like.

The active layer 20 may include a channel region, a source region, and a drain region for each of the transistors. For example, the source region and the drain region may be doped with an impurity, and the impurity may include an N-type impurity or a P-type impurity. The source region and the drain region may be electrically connected respectively to a first electrode (e.g., a source electrode) and a second electrode (e.g., a drain electrode) of the third conductive layer 40 (see FIG. 7) for each of the transistors.

Referring to FIG. 5, a first driving active layer ACT11 may include a first driving channel region CA11, and a first driving source region and a first driving drain region disposed at respective sides of the first driving channel region CA11. These regions correspond to transistor T11. A first switching active layer ACT12 may include a first switching channel region CA12, and a first switching source region and a first switching drain region disposed at respective sides of the first switching channel region CA12. These regions correspond to transistor T12. In addition, a first sensing active layer ACT13 may include a first sensing channel region CA13, and a first sensing source region and a first sensing drain region disposed at respective sides of the first sensing channel region CA13. These regions correspond to transistor T13.

FIG. 6 is a plan view illustrating an embodiment of a second conductive layer disposed on the active layer shown in FIG. 5. The second conductive layer provides lines for the unit pixel.

Referring to FIG. 6, a second conductive layer 30 may include a scan line pattern 121, a sensing control line pattern 123, a first lower electrode 141, a driving voltage line pattern 124, and a common voltage line pattern 125. The scan line pattern 121, the sensing control line pattern 123, the first lower electrode 141, the driving voltage line pattern 124, and the common voltage line pattern 125 may include the same material or different materials. For example, the scan line pattern 121, the sensing control line pattern 123, the first lower electrode 141, the driving voltage line pattern 124, and the common voltage line pattern 125 may include a metal, an alloy, a conductive metal oxide, a transparent conductive material, and the like, and be formed as a single layer or a multi-layer.

A portion or a protrusion portion of each of the scan line pattern 121, the sensing control line pattern 123, and the first lower electrode 141 may correspond to the gate electrode of each of the transistors T1 to T3 included in the first pixel circuit PC1 shown in FIG. 3.

Referring to FIGS. 5 and 6, the scan line pattern 121 may generally extend in the first direction DR1 according to a predetermined pattern, e.g., a zig-zag pattern. Also, the scan line pattern 121 may overlap with the first switching active layer ACT12 of the first switching transistor T12. An area in which the scan line pattern 121 and the first switching channel pattern CA12 overlap with each other may correspond to a gate electrode G12 of the first switching transistor T12.

The sensing control line pattern 123 may generally extend in the first direction DR1 also in a zig-zag pattern different from the pattern of scan line pattern 121. Also, the sensing control line pattern 123 may overlap with the first sensing active layer ACT13 of transistor T13. An area in which the sensing control line pattern 123 and the first sensing channel region CA13 overlap with each other may correspond to a gate electrode G13 of the first sensing transistor T13.

The first lower electrode 141 may be disposed between the scan line pattern 121 and the sensing control line pattern 123 along direction DR2. The first lower electrode 141 may overlap with the first driving active layer ACT11 of transistor T11. An area in which the first lower electrode 141 and the first driving channel region CA11 overlap with each other may correspond to a gate electrode G11 of the first driving transistor T11. The first lower electrode 141 may also serve as a lower storage plate of a first storage capacitor Cst1.

The driving voltage line pattern 124 may be separately formed for each pixel area and may extend between the scan line pattern 121 and the sensing control line pattern 123. Driving voltage line patterns of the first to third pixel areas PXA1 to PXA3 may be disposed to be spaced apart (and thus electrically disconnected) from each other in the first direction DR1. On the other hand, the common voltage line pattern 125 may extend in the first direction DR1 and may be shared by (or overlap with) the first to third pixel areas PXA1 to PXA3 or a larger number of pixel areas arranged in the first direction DR1.

FIG. 7 is a plan view illustrating an embodiment of a third conductive layer 40 disposed on the second conductive layer shown in FIG. 6. The third conductive layer 40 provides additional lines for the unit pixel.

Referring to FIG. 7, the third conductive layer 40 may include a scan line 171, a sensing control line 173, a first upper electrode 161, a driving voltage line 234, and a common voltage line 235. The scan line 171, the sensing control line 173, the first upper electrode 161, the driving voltage line 234, and the common voltage line 235 may include the same or different material. For example, the scan line 171, the sensing control line 173, the first upper electrode 161, the driving voltage line 234, and the common voltage line 235 may include a metal, an alloy, a conductive metal oxide, a transparent conductive material, and the like, and be formed as a single layer or a multi-layer.

Referring to FIGS. 6 and 7, the scan line 171 may be disposed at an upper side of the first upper electrode 16 for 1 in the first direction DR1 and extends in the second direction DR2. The scan line 171 may be connected to the scan line pattern 121 of the second conductive layer 30 through a contact hole 121a. The scan line 171 may serve as the scan line SCLi included in the first pixel circuit PC1 shown in FIG. 3.

The sensing control line 173 may be disposed at a lower side of the first upper electrode 161 in the first direction DR1 and may extend in the second direction DR2. The sensing control line 173 may be connected to the sensing control line pattern 123 of the second conductive layer 30 through a contact hole 123a. The sensing control line 173 may serve as the sensing control line SSLi included in the first pixel circuit PC1 shown in FIG. 3.

An initialization voltage line 233 may be disposed to extend in the first direction DR1 adjacent to the sensing control line pattern 123 (FIG. 6). The initialization voltage line 233 may be connected to the first sensing source region or the first sensing drain region of the first sensing active layer ACT13 (see FIG. 5) through a contact hole 133a. The initialization voltage line 233 may serve as the sensing line SLj for supplying the initialization voltage Vint shown in FIG. 3.

The driving voltage line 234 may be disposed to overlap with the driving voltage line pattern 124 (FIG. 6). Accordingly, the driving voltage line 234 may be separately formed for each pixel area. Also, the driving voltage line 234 may be connected to the first driving source region or the first driving drain region of the first driving active layer ACT11 of transistor T11 (see FIG. 5) through a contact hole 135a. Also, the driving voltage line 234 may be connected to the driving voltage line pattern 124 of the second conductive layer 30 through another contact hole 135b.

The common voltage line 235 may be disposed to overlap with the common voltage line pattern 125. The common voltage line 235 may be shared by a plurality of pixels PXA1, PXA2, and PXA3. The common voltage line 235 may be connected to the common voltage line pattern 125 of the second conductive layer 30 (FIG. 6) through a contact hole 131b. As such, the driving voltage line 234 and the common voltage line 235 may be formed in a double-layer structure. Also, the driving voltage line 234 and the common voltage line 235 may respectively serve as power lines for supplying the driving voltage ELVDD and the common voltage ELVSS, which are shown, for example, in FIG. 3.

The first upper electrode 161 may be separately provided in each pixel area. First upper electrodes of the first to third pixel areas PXA1 to PXA3 may be disposed to be spaced apart from each other in the first direction DR1. Also, the first upper electrode 161 may be disposed to overlap with the first lower electrode 141.

The first upper electrode 161 may be connected to the first driving source region or the first driving drain region of the first driving active layer ACT11 of transistor T11 (see FIG. 5) through a contact hole 161a. Also, the first upper electrode 161 may be connected to the first sensing source region or the first sensing drain region of the first sensing active layer ACT13 of transistor T13 (see FIG. 5) through another contact hole 161b.

The first upper electrode 161 may be a first electrode (e.g., a source electrode) or a second electrode (e.g., a drain electrode) of the first driving transistor T11, and may also serve as an upper storage plate of the first storage capacitor Cst1. The first upper electrode 161 and the first lower electrode 141 may form the first storage capacitor Cst1 shown in FIG. 3.

The second data line 152 among the data lines 150 may be connected to the first switching source region or the first switching drain region of the first switching active layer ACT12 of transistor T12 (see FIG. 5) through a contact hole 150a.

FIG. 8 is a plan view illustrating an embodiment of a pixel electrode layer 50 disposed on the third conductive layer 40 shown in FIG. 7.

Referring to FIG. 8, the pixel electrode layer 50 may include a first pixel electrode 320R, a second pixel electrode 320G, and a third pixel electrode 320B. Also, the pixel electrode layer 50 may also include an auxiliary electrode 340.

The first pixel electrode 320R, the second pixel electrode 320G, and the third pixel electrode 320B are adjacent to each other and are disposed in a predetermined pattern, but may be disposed to not overlap with each other. The first pixel electrode 320R may overlap with a first contact hole CNTH1. As described in greater detail below, the first contact hole CNTH1 (see also FIG. 11) may be filled with an insulating pattern when a corresponding one of the pixels is found to be defective. The insulating pattern may therefore repair the defective pixel by preventing the pixel from emitting light. The second pixel electrode 320G may overlap with a second contact hole CNTH2. In addition, the third pixel electrode 320B may overlap with a third contact hole CNTH3. These additional holes may also include the insulating pattern in the event that their pixels are found to be defective.

Referring to FIGS. 7 and 8, the first pixel electrode 320R may be connected to the first upper electrode 161 through the first contact hole CNTH1 when the pixel is not defective. The first pixel electrode 320R may be connected to the first upper electrode 161, to be connected to the first electrode (e.g., the source electrode) or the second electrode (e.g., the drain electrode) of the first driving transistor T11. When the pixel is defective, the insulating pattern (FIG. 11) blocks electrical connection between the first pixel electrode 320R and the first electrode or the second electrode of the first driving transistor T11. Also, the first pixel electrode 320R may be connected to the lower electrode 141 of the second conductive layer 30 through the first upper electrode 161.

The first pixel electrode 320R may be disposed to overlap with the driving voltage line 234. Also, the first pixel electrode 320R may be disposed not to overlap with the sensing control line 173 (e.g., see FIG. 7).

Similarly, the second pixel electrode 320G may be connected to a first upper electrode of the second pixel area PXA2 through the second contact hole CNTH2, and the third pixel electrode 320B may be connected to a first upper electrode of the third pixel area PXA3 through the third contact hole CNTH3.

The auxiliary electrode 340 may be disposed at one side of the first pixel electrode 320R in the second direction DR2. The auxiliary electrode 340 may be connected to the common voltage line 235 (e.g., see FIG. 7) through a fourth contact hole CNTH4.

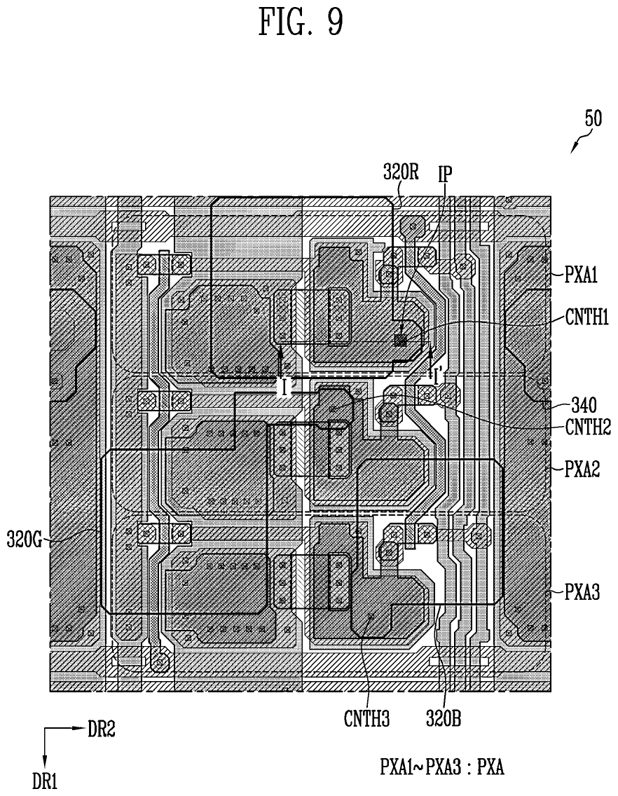

FIG. 9 is a plan view illustrating an example of the insulating pattern IP provided in a unit pixel shown in FIG. 8.

Referring to FIGS. 9 and 11, when a defect occurs in pixel circuits according to an electrical inspection result, the insulating pattern IP may be disposed in at least one of the first to third contact holes CNTH1 to CNTH3.

In accordance with an embodiment, when a defect occurs in the first pixel circuit PC1 of the first pixel PX1, the first contact hole CNTH1 may be filled with the insulating pattern IP before the first pixel electrode 320R. As a result, the first pixel circuit PC1 and the first pixel electrode 320R are electrically disconnected from each other by the insulating pattern IP, so that deterioration of an electrical characteristic according to a lighting defect of the first pixel PX1 can be prevented or at least reduced. For example, a leakage current in the first pixel circuit PC1 and/or the first pixel electrode 320R may be blocked or at least reduced. Thus, an electrical characteristic of the first pixel PX1 may be repaired in this manner when the first pixel PX1 is defective. The first contact hole CNTH1 may be a contact hole overlapping with the first pixel electrode 320R of the first pixel PX1 in which a defect occurs in the first pixel circuit PC1. The first contact hole CNTH1 may be a contact hole connected to the first upper electrode 161.

The insulating pattern IP may include an inorganic material or an organic material. For example, the inorganic material may include silicon oxide, silicon nitride, silicon oxynitride, and the like, and be used along or in a combination thereof. In addition, the organic material may include a carbon component, and include acrylic resin, epoxy resin, phenolic resin, polyamide resin, polyimide resin, and the like.

The insulating pattern IP may be formed in the first contact hole CNTH1 using, for example, an inkjet method. For example, when a defect occurs in the first pixel circuit PC1 of the first pixel PX1, an insulating ink may be applied to fill in the first contact hole CNTH1 through a corresponding inkjet nozzle. The filling process may entirely or partially fill the first contact hole CNTH1. In one embodiment of applying the insulating ink, the insulating pattern IP may be formed at a bottom surface and a side surface of the first contact hole CNTH1. In one embodiment, the insulating ink may be a solvent including the same material as the insulating pattern IP.

In this manner, the first pixel circuit PC1 corresponding to a defective pixel circuit may be separated from the first pixel electrode 320R by the insulating pattern IP disposed in the first contact hole CNTH1. For example, the first electrode (e.g., the source electrode) or the second electrode (e.g., the drain electrode) of the first driving transistor T11 included in the first pixel circuit PC1 may be electrically separated (or disconnected) from the first pixel electrode 320R by the insulating pattern IP disposed in the first contact hole CNTH1. Accordingly, the first pixel PX1 may be blackened, e.g., not emit light.

On the other hand, the other second and third pixels PX2 and PX3 except the first pixel PX1 may be electrically connected to each other through the second and third contact holes CNTH2 and CNTH3 to normally emit light.

As such, a defective pixel of the display device DD may be blackened, e.g., not emit light. A pixel electrode of the defective pixel may remain in an emission area of the display device DD, and maintain a visibility similar to visibilities of peripheral normal pixels due to external light reflection. Thus, deterioration in the quality of the display device DD can be suppressed or prevented.

Furthermore, since the insulating pattern IP is disposed in the first contact hole CNTH1, any separate space margin for a process of blocking the first pixel electrode 320R from the first pixel circuit PC1 may not be required. In addition, a repair process performed by laser cutting using a mask pattern may be omitted. Thus, manufacturing costs can be reduced.

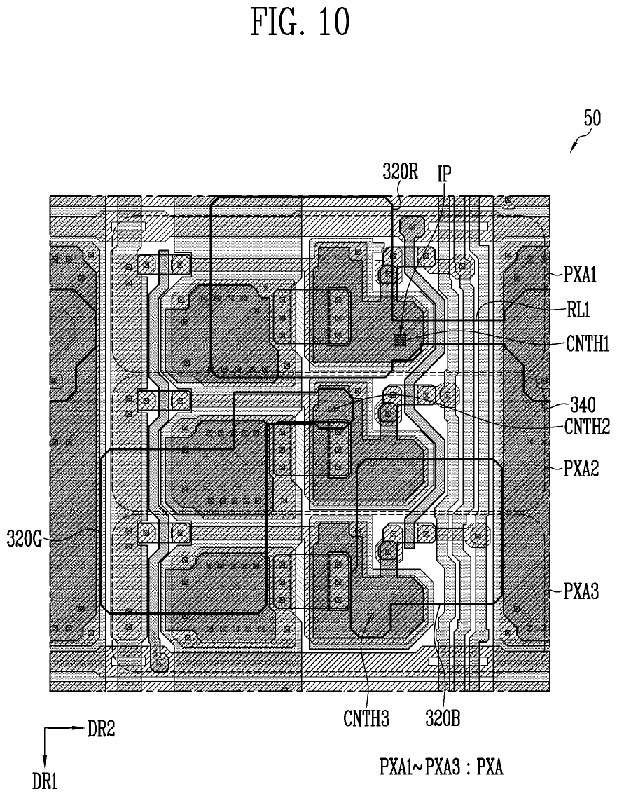

FIG. 10 is a plan view illustrating a repair line provided in the unit pixel shown in FIG. 9. The repair line may be formed when the results of the electrical inspection indicates that a corresponding pixel is defective. As will be described in greater detail below, the repair line may stabilize the voltage of the pixel electrode of the defective pixel, which may otherwise be in a floating or other unstable state.

Referring to FIG. 10, a pixel electrode overlapping the insulating pattern IP may be electrically connected to the common voltage line 235 (see FIG. 7) through the repair line.

In accordance with an embodiment, when a defect occurs in the first pixel circuit PC1 of the first pixel PX1, a first repair line RL1 may be formed between the first pixel electrode 320R overlapping with the insulating pattern IP and the auxiliary electrode 340. The auxiliary electrode 340 may be connected to the common voltage line 235 through the fourth contact hole CNTH4 (see FIG. 8).

The first repair line RL1 may be formed between the first pixel electrode 320R and the auxiliary electrode 340 using, for example, an inkjet method. For example, when the insulating pattern IP is formed in the first contact hole CNTH1, conductive ink may be sprayed through an inkjet nozzle. The conductive ink may be sprayed onto the same layer as the first pixel electrode 320R. The conductive ink may be a conductive material including nano particles of a predetermined material, such as silver Ag.

For example, the first repair line RL1 may be formed by printing the conductive material in the same layer as the first pixel electrode 320R. Accordingly, any additional processes for forming the first repair line RL1, such as a deposition process and a patterning process, are not required. Thus, manufacturing processes can be simplified, and manufacturing costs can be reduced.

In addition, the first pixel electrode 320R may be connected to the auxiliary electrode 340 through the first repair line RL1. When the first pixel electrode 320R is separated from the first pixel circuit PC1 by the insulating pattern IP, a voltage of the first pixel electrode 320R may become unstable. The first pixel electrode 320R and the common voltage line 235 are connected to each other through the first repair line RL1, so that the voltage of the first pixel electrode 320R can be stabilized. For example, a voltage of the common voltage line 235 may be equal to a cathode voltage applied to the light emitting elements 410 to 430 (see FIG. 2). The first pixel area PXA1 can be more stably blackened, e.g., more stably placed in a state where light emission will not occur.

On the other hand, the second and third pixel circuits PC2 and PC3 included in the second and third pixels PX2 and PX3 (except the first pixel PX1) may be normal pixel circuits. Accordingly, repair lines may not be formed in the second and third pixel circuits PC2 and PC3.

FIG. 11 is a sectional view illustrating portions of a pixel circuit and a light emitting element, taken along line I-I′ shown in FIG. 9. In FIG. 11, the pixel circuit is defective and thus includes the insulating pattern IP as previously explained.

Referring to FIG. 11, a plurality of insulating layers may be disposed on a substrate SUB. The plurality of insulating layers may be disposed between the first conductive layer 10, the active layer 20, the second conductive layer 30, the third conductive layer 40, and the pixel electrode layer 50, which are described above.

A buffer layer BUF may be disposed over the first conductive layer 10 (see FIG. 4). The buffer layer BUF may include an inorganic insulating material covering the first conductive layer 10. For example, the buffer layer BUF may include an oxide layer such as silicon oxide (SiOx) or a nitride layer such as silicon nitride (SiNx). The buffer layer BUF may prevent metal atoms or impurities from being diffused into the active layer 20 from the first conductive layer 10.

A gate insulating layer GI may be disposed between the active layer 20 (see FIG. 5) and the second conductive layer 30 (see FIG. 6). In addition, an interlayer insulating layer ILD may be disposed between the second conductive layer 30 and the third conductive layer 40 (see FIG. 7).

A planarization insulating layer PVX may be disposed over the third conductive layer 40. The planarization insulating layer PVX may be interposed between pixel circuits and a light emitting element. The planarization insulating layer PVX may prevent damage of pixel circuits or extraction of metal in a subsequent process. Also, the planarization insulating layer PVX may stably support light emitting elements.

Referring to FIGS. 9 and 11, as a result of the repair process, the first pixel PX1 may include the insulating pattern IP in the first contact hole CNTH1, which is formed in the planarization insulating layer PVX, for example, by the inkjet process previously discussed. The first pixel circuit PC included in the first pixel PX1 may correspond to a defective pixel circuit. As shown in FIG. 11, the insulating pattern at least partially fills the first contact hole CNTH1 to electrically disconnected the first pixel circuit PC (e.g., a drain or source region of transistor T11) from the light emitting element.

In accordance with an embodiment, the first contact hole CNTH1 may expose a first electrode (e.g., a source electrode) A11 or a second electrode (e.g., a drain electrode) A12 of the first driving transistor T11 while penetrating the planarization insulating layer PVX. In FIG. 11, it is exemplarily illustrated that the first contact hole CNTH1 overlaps with the first electrode A11 of the first driving transistor T11. The first contact hole CNTH1 may be disposed between the first pixel electrode 320R and the first electrode A11 of the first driving transistor T11.

When the first pixel circuit PC1 included in the first pixel area PXA1 is a defective pixel circuit, the insulating pattern IP may be disposed in the first contact hole CNTH1. The insulating pattern IP disposed in the first contact hole CNTH1 may electrically separate (or disconnect) the first electrode A11 of the first driving transistor T11 from the first pixel electrode 320R. Accordingly, the first pixel PX1 may be blackened, e.g., not emit light.

The first pixel electrode 320R may be disposed on the planarization insulating layer PVX. A pixel defining layer PDL may be disposed on the planarization insulating layer PVX. The pixel defining layer PDL may define an emission area. The pixel defining layer PDL may expose an upper surface of the first pixel electrode 320R. An intermediate layer 310 may be disposed on the first pixel electrode 320R exposed by the pixel defining layer PDL. The intermediate layer 310 may include a light emitting layer 312. In addition, the light emitting layer 312 may include an organic material including a fluorescent or phosphorescent material emitting light of a predetermined color, e.g., red, green, blue or white. Functional layers 311 and 313 such as a hole transport layer (HTL), a hole injection layer (HIL), an electron transport layer (ETL), and an electron injection layer (EIL) may be selectively further disposed on the top/bottom of the light emitting layer 312. A common electrode 330 may be disposed on the light emitting layer 312. The first pixel electrode 320R, the light emitting layer 312, and a portion of the common electrode 330 may serve as the first light emitting element 410 (see FIG. 3).

In one embodiment, the first pixel electrode 320R may be a reflective electrode, and the common electrode 330 may be a transmissive electrode.

Hereinafter, a method of manufacturing the display device described with reference to FIGS. 1 to 11 will be described.

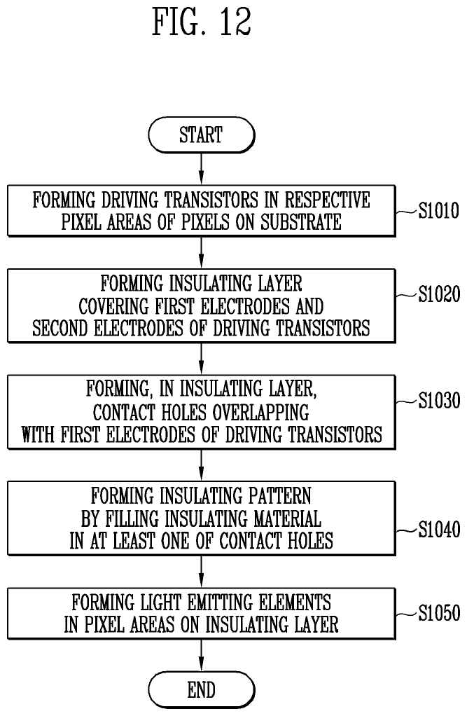

FIG. 12 is a flowchart illustrating an embodiment of a method of manufacturing the display device.

Referring to FIGS. 11 and 12, in S1010, driving transistors may be formed in respective pixel areas (or pixel circuits) of pixels on the substrate SUB.

In S1020, the planarization insulating layer PVX may be formed, which covers first electrodes and second electrodes of the driving transistors. The planarization insulating layer PVX may be considered to be included in the pixel circuit or may be considered to be a layer between the pixel circuit and the light emitting element.

In S1030, contact holes overlapping with the first electrodes of the driving transistors may be formed in the planarization insulating layer PVX. The contact holes may expose the first electrodes of the driving transistors while penetrating the planarization insulating layer PVX.

In S1040, an insulating pattern IP may be formed in at least one CNTH1 of the contact holes (see e.g., FIG. 11). When a defect occurs in the first pixel circuit PC1 shown in FIG. 2, the insulating pattern IP may be formed in the first contact hole CNTH1 formed in the first pixel circuit PC1. The insulating pattern IP may be formed in the first contact hole CNTH1 using, for example, an inkjet method as previously explained. Thus, when a defect occurs in the first pixel circuit PC1, an insulating ink may be partially or entirely filled in the first contact hole CNTH1 through an inkjet nozzle. For example, in forming the filled insulating ink, the insulating pattern IP may be formed at a bottom surface and a side surface of the first contact hole CNTH1. The insulating ink may be a solvent including the same material as the insulating pattern IP.

As such, the insulating pattern IP disposed in the first contact hole CNTH1 may electrically separate (or disconnect) the first electrode A11 of the first driving transistor T11 from the first pixel electrode 320R formed subsequently, thereby preventing the light emitting element from emitting light.

In S1050, light emitting elements may be formed in the pixel areas on the planarization insulating layer PVX. For example, pixel electrodes may be formed on the planarization insulating layer PVX, light emitting layers may be formed on the pixel electrodes, and a common electrode may be formed on the light emitting layers.

The first pixel circuit PC1 corresponding to a defective pixel circuit may be separated (electrically disconnected) from the first pixel electrode 320R by the insulating pattern IP disposed in the first contact hole CNTH1. For example, the first electrode A11 of the first driving transistor T11 included in the first pixel circuit PC1 may be electrically separated from the first pixel electrode 320R by the insulating pattern IP disposed in the first contact hole CNTH1. Accordingly, the first pixel PX1 may be blackened, e.g., may not emit light.

On the other hand, no insulating pattern may be formed in contact holes of the other second and third pixels PX2 and PX3 except the first pixel PX1. Therefore, the other second and third pixels PX2 and PX3 may normally emit light.

Accordingly, a defective pixel of the display device DD can be efficiently blackened, e.g., rendered inoperative or placed in a state where no light is emitted. A pixel electrode of the defective pixel may remain in an emission area of the display device DD, and maintain visibility similar to visibilities of peripheral normal pixels due to external light reflection. Thus, quality deterioration of the display device DD can be suppressed or prevented.

In addition, since the insulating pattern IP is disposed in the contact hole, any separate space margin for a process of blocking the first pixel electrode 320R from the first pixel circuit PC1 may not be required. In addition, the a repair laser cutting process using a mask pattern may be omitted. Thus, manufacturing costs can be reduced.

In accordance with the present disclosure, there can be provided a display device and a method of manufacturing the same, which can have increased efficiency by repairing a lighting defect of a pixel. In one embodiment, the repairing process may be understood as rendering inoperative the defective pixel, e.g., placing the defective pixel in a state where it does not emit light.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims. The embodiments may be combined to form additional embodiments.

What is claimed is:

1. A display device comprising:
a substrate;
driving transistors disposed in pixel areas on the substrate, each of the driving transistors including a first electrode and a second electrode;
an insulating layer disposed over the driving transistors to cover the first electrodes and the second electrodes of the driving transistors, the insulating layer having contact holes respectively overlapping with the first electrodes of the driving transistors;
light emitting elements disposed on the insulating layer, the light emitting elements including pixel electrodes respectively overlapping with the first electrodes of the driving transistors; and
an insulating pattern disposed in at least one of the contact holes to prevent a corresponding one of the pixel areas from emitting light.

2. The display device of claim 1, wherein:
the pixel electrodes include a first pixel electrode and a second pixel electrode,
the first pixel electrode overlaps with the insulating pattern, and
the first pixel electrode is electrically separated from a first electrode overlapping with the first pixel electrode among the first electrodes of the driving transistors by the insulating pattern.

3. The display device of claim 2, wherein the second pixel electrode is electrically connected to a first electrode overlapping with the second pixel electrode among the first electrodes of the driving transistors through another of the contact holes.

4. The display device of claim 1, wherein the insulating pattern includes an inorganic material or an organic material.

5. The display device of claim 1, wherein:
pixel circuits are respectively disposed in the pixel areas on the substrate,
the pixel circuits include the driving transistors, and
a pixel circuit of a pixel area overlapping with the insulating pattern among the pixel areas corresponds to a defective pixel circuit.

6. The display device of claim 1, further comprising:
a repair line extending to overlap with a common voltage line from a first pixel electrode overlapping with the insulating pattern among the pixel electrodes.

7. The display device of claim 6, wherein:
the common voltage line is disposed on a bottom of the insulating layer, and
the repair line is electrically connected to the common voltage line through another contact hole formed in the insulating layer.

8. The display device of claim 6, wherein the repair line is formed in a same layer as the first pixel electrode.

9. The display device of claim 6, wherein the repair line includes a conductive material.

10. The display device of claim 6, wherein the first pixel electrode is electrically connected to the common voltage line by the repair line.

11. The display device of claim 6, wherein:
the pixel areas extend in a first direction, and
the common voltage line extends in the first direction to overlap with the pixel areas.

12. A method of manufacturing a display device, the method comprising:
forming driving transistors, each of the driving transistors including a first electrode and a second electrode in pixel areas on a substrate;
forming an insulating layer covering the first electrodes and the second electrodes of the driving transistors, the insulating layer having contact holes respectively overlapping with the first electrodes of the driving transistors; and
forming, on the insulating layer, light emitting elements including pixel electrodes respectively overlapping with the first electrodes of the driving transistors,
wherein forming the insulating layer includes forming an insulating pattern in at least one of the contact holes to prevent a corresponding one of the pixel areas from emitting light.

13. The method of claim 12, wherein:
the pixel electrodes include a first pixel electrode and a second pixel electrode,
the first pixel electrode overlaps with the insulating pattern, and
the first pixel electrode is electrically separated from a first electrode overlapping with the first pixel electrode among the first electrodes of the driving transistors by the insulating pattern.

14. The method of claim 13, wherein the second pixel electrode is electrically connected to a first electrode overlapping with the second pixel electrode among the first electrodes of the driving transistors through another of the contact holes.

15. The method of claim 12, wherein the insulating pattern includes an inorganic material or an organic material.

16. The method of claim 12, further comprising:
forming a repair line extending to overlap with a common voltage line from a first pixel electrode overlapping with the insulating pattern among the pixel electrodes.

17. The method of claim 16, wherein the first pixel electrode is electrically connected to the common voltage line by the repair line.

18. The method of claim 16, wherein the repair line includes a conductive material.

19. A pixel, comprising:
a light emitting element;
a pixel circuit configured to drive the light emitting element; and
an insulating pattern to electrically disconnect the pixel circuit from the light emitting element when the pixel is defective.

20. The pixel of claim 19, further comprising:
a planarization insulating layer between a driving transistor of the pixel circuit and the light emitting element, wherein the planarization insulating layer includes a contact hole which includes the insulating pattern.

21. The pixel of claim 19, further comprising:
a repair line electrically connecting an electrode of the light emitting element to a supply voltage, the supply voltage configured to stabilize the electrode of the light emitting element when the pixel is defective.

22. The pixel of claim 19, wherein the insulating pattern includes an insulating ink.
